(19) United States
(12) Patent Application Publication
(10) Pub. No.: US 2009/0261406 A1
(43) Pub. Date: Oct. 22, 2009

(54) USE OF SILICON-RICH NITRIDE IN A FLASH MEMORY DEVICE

(76) Inventors: Youseok SUH, Cupertino, CA (US); Shenqing FANG, Fremont, CA (US); Kuo Tung CHANG, Saratoga, CA (US); Rinji SUGINO, San Jose, CA (US); Yi MA, Santa Clara, CA (US); Eunha KIM, Menlo Park, CA (US)

Correspondence Address: SPANSION LLC C/O MURABITO , HAO & BARNES LLP, TWO NORTH MARKET STREET, THRID FLOOR, SAN JOSE, CA, 95113, US

(21) Appl. No.: 12/105,208

(22) Filed: Apr. 17, 2008

(51) Int. Cl. H01L 29/792; H01L 21/336

(52) U.S. Cl. 257/325; 438/287; 257/E29.309; 257/E21.423

(57) ABSTRACT

A flash memory cell includes a charge storage element that includes at least a first layer and a second layer. One of the layers includes silicon-rich silicon nitride and the other layer includes silicon nitride. More specifically, the ratio of silicon-to-nitrogen in the first layer is greater than the ratio of silicon-to-nitrogen in the second layer.

### TECHNICAL FIELD

Embodiments in accordance with the present invention generally relate to semiconductor devices such as flash memory cells.

### BACKGROUND

A traditional flash memory cell has a programmed state and an erased state. In the programmed state, a quantity or level of electrical charge is stored in a charge storage element. In the erased state, the charge is removed. The threshold voltage associated with the programmed state is higher than the threshold voltage associated with the erased state. A read voltage is applied to the memory cell—if a current is detected at the read voltage, the cell is read as erased; otherwise, the cell is read as programmed.

A typical memory cell cycles between the programmed state and the erased state many times during its lifetime. As the number of cycles increases, the memory cell in the erased state may not be sufficiently discharged, resulting in sub-threshold slope (STS) degradation. Consequently, the voltage difference between the programmed and erased states may decrease, making it more difficult to distinguish between the two states. As a result, a read error may occur—for example, if the memory cell is not sufficiently discharged, then it may be read as being in the programmed state when in fact it is in the erased state.

Accordingly, a solution for STS degradation in memory cells would be advantageous. Embodiments in accordance with the present invention provide this and other advantages.

### SUMMARY

According to an embodiment of the present invention, a flash memory cell includes a charge storage element. The charge storage element includes at least a first layer and a second layer, which have different compositions of silicon nitride, respectively. One of the layers includes silicon-rich silicon nitride and the other layer includes silicon nitride. The introduction of silicon-rich silicon nitride in the charge storage element ameliorates the effects of STS degradation, reducing the number of read errors associated with STS degradation and thus improving the performance of memory cells.

These and other objects of the various embodiments of the present invention and their advantages will be recognized by those of ordinary skill in the art after reading the following detailed description of the embodiments that are illustrated in the various drawing figures.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1 illustrates a cross-sectional view of a portion of a memory cell according to one embodiment of the present invention.

FIG. 2 illustrates a cross-sectional view of a portion of a memory cell according to another embodiment of the present invention.

FIG. 3 is a flowchart of a method for forming memory cells according to one embodiment of the present invention.

The drawings referred to in this description should be understood as not being drawn to scale except if specifically noted.

### DETAILED DESCRIPTION

Reference will now be made in detail to embodiments of the invention, examples of which are illustrated in the accompanying drawings. While the invention will be described in conjunction with these embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, the present invention may be practiced without these specific details. In other instances, well-known methods, procedures, components, and circuits have not been described in detail as not to unnecessarily obscure aspects of the present invention.

Some portions of the detailed descriptions that follow are presented in terms of procedures, logic blocks, processing, and other symbolic representations of operations for fabricating semiconductor devices. These descriptions and representations are the means used by those skilled in the art of semiconductor device fabrication to most effectively convey the substance of their work to others skilled in the art. In the present application, a procedure, logic block, process, or the like, is conceived to be a self-consistent sequence of steps or instructions leading to a desired result. The steps are those requiring physical manipulations of physical quantities. It should be borne in mind, however, that all of these and similar terms are to be associated with the appropriate physical quantities and are merely convenient labels applied to these quantities. Unless specifically stated otherwise as apparent from the following discussions, it is appreciated that throughout the present application, discussions utilizing terms such as “forming,” “performing,” “producing,” “depositing,” “filling,” “implanting” or the like, refer to actions and processes of semiconductor device fabrication.

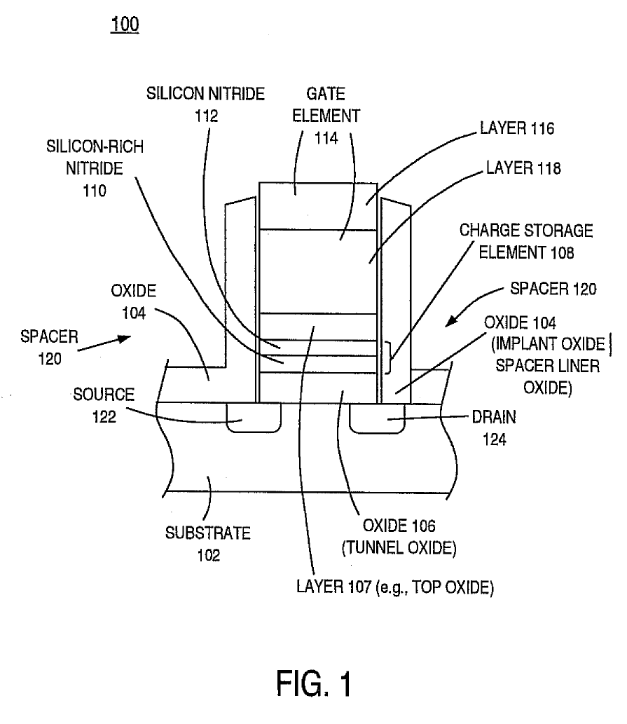

FIG. 1 illustrates a cross-sectional view of a portion of a memory cell 100 according to one embodiment of the present invention. The memory cell 100 is an example of one memory cell in an array of memory cells in a memory device such as a flash memory device. The memory cells in a memory array conventionally lie at or near the points at which word lines cross over bit lines.

In FIG. 1 as well as in the other figures included herein, only certain elements central to an understanding of the present invention are illustrated and described. For example, a memory cell or memory array according to the present invention may include elements in addition to, as an alternative to, the elements described herein.

In the example of FIG. 1, the memory cell 100 is formed on a substrate 102 (e.g., a silicon or silicon-based substrate) that includes a source region 122 and a drain region 124. The memory cell 100 also includes a gate element 114. In one embodiment, the gate element 114 includes a metal silicide layer (e.g., cobalt silicide), a metal nitride layer, or a metal layer 116 disposed over a polysilicon layer 118.

A charge storage element 108 is disposed between the gate element 114 and the substrate 102. In the embodiment of FIG. 1, the charge storage element 108 includes different composition silicon nitride layers 110 and 112. In this embodiment, the silicon nitride layer 112, which may also be referred to herein as a second layer, is disposed over the silicon-rich silicon nitride layer 100, which may also be referred to herein as a first layer.

Generally speaking, the ratio of silicon-to-nitrogen in the silicon-rich silicon nitride layer 110 is greater than the ratio of silicon-to-nitrogen in the silicon nitride layer 112. More specifically, silicon-rich silicon nitride is a type of silicon nitride that has a greater number of silicon atoms than the number of silicon atoms in stoichiometric silicon nitride. Stoichiometric silicon nitride has the chemical formula SiₓN_{y} where x=3 and y=4. While silicon-rich silicon nitride also has the chemical formula SiₓN_{y}, it has a composition where the ratio of x-to-y is greater than three-fourths. Silicon-rich silicon nitride has more desirable conductive properties relative to stoichiometric silicon nitride. Silicon-rich silicon nitride tends to have shallower trap energy levels and higher trap density, both of which allow electrons to move easily to enable more effective Fowler-Nordheim programming and erasing.

When the memory cell 100 is programmed, a relatively uniform charge is trapped across the whole channel (across the width of the charge storage element 108, where width is measured left-to-right considering the orientation of the memory cell in FIG. 1). In the erased state, the charges are removed from storage element 108. The introduction of silicon-rich silicon nitride in the charge storage element ameliorates the effects of sub-threshold slope (STS) degradation by changing the charge trap depth (a shallow trap depth is desirable). In particular, the introduction of silicon-rich silicon nitride improves discharge at the edges of the charge storage element 108. Consequently, the number of read errors associated with severe STS degradation is reduced, improving the performance of memory cells.

The charge storage 108 element may be separated from the substrate 102 by an oxide layer 106 (which may be referred to as a bottom oxide or tunnel oxide layer). The charge storage element 108 may be separated from the gate element 114 by a top oxide layer or a high-k (high dielectric constant) material layer 107. The high-k material has a dielectric constant greater than that of silicon dioxide.

A spacer 120 is formed on each side of the memory cell 110. The spacer 120 may be formed using a nitride material or an oxide material. The spacer 120 may be separated from the elements of the memory cell 110 by one or more oxide layers 104 (e.g., the oxide layer 104 may include an implant oxide layer and a spacer liner oxide layer).

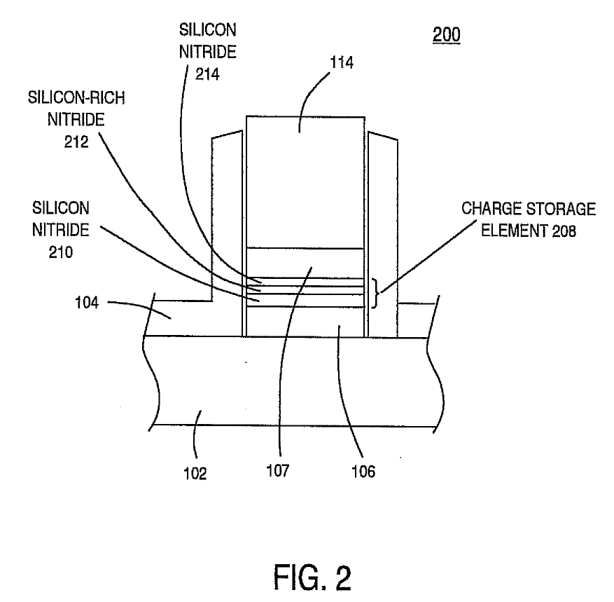

FIG. 2 illustrates a cross-sectional view of a portion of a memory cell 200 according to another embodiment of the present invention. In many aspects, the memory cell 200 is similar to the memory cell 100 of FIG. 1. One difference between the memory cells 100 and 200 is that, in the memory cell 200, the silicon-rich silicon nitride layer 212 is sandwiched between a silicon nitride layer 214 and a silicon nitride layer 210 (the latter may also be referred to herein as a third layer). The ratio of silicon-to-nitrogen in the silicon-rich silicon nitride layer 212 is greater than the ratio of silicon-to-nitrogen in the silicon nitride layer 210, and is also greater than the ratio of silicon-to-nitrogen in the silicon nitride layer 214.

In general, a memory array includes a number of word lines and a number of bit lines that are disposed orthogonal to the word lines. The charge storage element 108 is adjacent to each of the word lines. In one embodiment, a memory cell includes a portion of a word line and its associated charge storage element as well as a portion of two neighboring bit lines. In one such embodiment, the source/drain regions, which correspond to the two neighboring bit lines, are interchangeable with each other—that is, when one region operates as a source, the other operates as a drain, and vice versa. Charge storage elements can be continuous under the layer 118 (e.g., the polysilicon layer) or they can be isolated for each memory cell.

In addition to the flash memory cell embodiments described above, features of the invention can be incorporated into flash memory cells such as, but not limited to, SONOS (semiconductor-oxide-nitride-oxide-semiconductor) architectures and TANOS (tantalum-alumina-nitride-oxide-semiconductor) architectures. That is, for example, the nitride layer referred to in the SONOS and TANOS architectures can be modified to include a silicon-rich silicon nitride layer along with one or more silicon nitride layers in the manner described above.

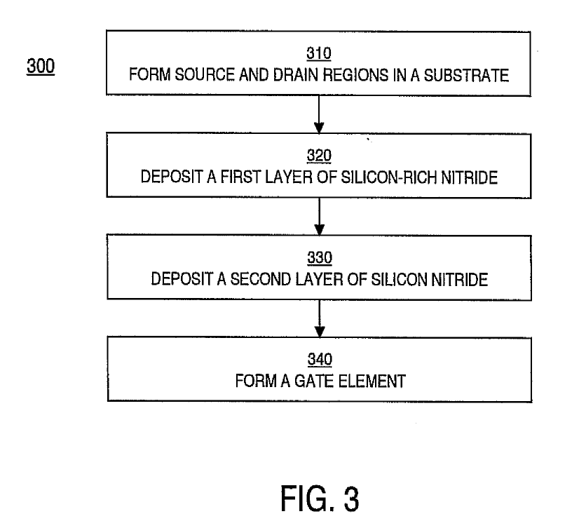

FIG. 3 is a flowchart 300 of a method for forming memory cells according to one embodiment of the present invention. Although specific steps are disclosed in flowchart 300, such steps are exemplary. That is, the present invention is well suited to performing variations of the steps recited in flowchart 300. It is also appreciated that other processes and steps associated with the fabrication of memory cells may be performed along with the process illustrated by FIG. 3; that is, there may be a number of process steps before, during and after the steps shown and described by FIG. 3. Importantly, embodiments of the present invention can be implemented in conjunction with these other (e.g., conventional) processes and steps without significantly perturbing them. Generally speaking, process steps associated with the various embodiments of the present invention can be added to a conventional process without significantly affecting the peripheral processes and steps.

Various techniques known in the art are used to fabricate a semiconductor device such as a memory cell. In general, these techniques involve repeating, with variations, a number of characteristic steps or processes. One of these characteristic steps or processes involves applying a layer of material to an underlying substrate or to a preceding layer, and then selectively removing the material using, for example, an etch process. Another of the characteristic steps or processes involves selectively adding a dopant material to the substrate or to one or more of the subsequent layers, in order to achieve desirable electrical performance. Using these characteristic processes, a semiconductor, generally comprising different types of material, can be accurately formed. These characteristic processes are known in the art, and so are not elaborated upon herein.

FIG. 3 is discussed in conjunction with FIGS. 1 and 2. In block 310, regions that can be used as source and drain regions are formed in a substrate. In block 320, a layer of silicon-rich silicon nitride (e.g., the layer 110 or the layer 212) is deposited. In one embodiment, an oxide layer (e.g., the layer 106) is formed. In another embodiment, before the layer of silicon-rich silicon nitride is deposited, a layer of silicon nitride (e.g., the layer 210) is deposited.

In block 330, a layer of silicon nitride (e.g., the layer 112 or the layer 214) is deposited. Because the amount of silicon may be reduced during a subsequent oxidation step, the amount of silicon deposited in the first, second and third layers may be greater than the amount of silicon desired in the final product.

In block 340, a gate element is formed. In one embodiment, an oxide layer (e.g., the layer 107) is formed.

As part of the method above, spacers and other oxide layers (e.g., the implant oxide layer and the spacer liner oxide layer) can be formed.

In summary, a charge storage element in a memory cell includes a silicon-rich silicon nitride layer in addition to one or more layers of silicon nitride. The introduction of a silicon-rich silicon nitride layer in the charge storage element ameliorates the effects of STS degradation, reducing the number of read errors and improving performance.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

What is claimed is:

1. A flash memory cell comprising:
a substrate comprising a source and a drain;
a gate element; and
a charge storage element disposed between said substrate and said gate element, said charge storage element comprising a first layer comprising silicon-rich silicon nitride and a second layer comprising silicon nitride, wherein said first layer comprises a higher silicon-to-nitrogen ratio than said second layer.

2. The flash memory cell of claim 1 wherein said charge storage element comprises a third layer comprising silicon nitride, wherein said first layer is sandwiched between said second layer and said third layer, and wherein said first layer comprises a higher silicon-to-nitrogen ratio than said third layer.

3. The flash memory cell of claim 1 further comprising a layer of material disposed between said charge storage element and said gate element, said material selected from the group consisting of: an oxide, and a high dielectric constant material.

4. The flash memory cell of claim 1 further comprising a tunnel oxide layer disposed between said charge storage element and said substrate.

5. The flash memory cell of claim 1 wherein said gate element comprises a layer of material selected from the group consisting of: a metal silicide; a metal nitride, and a metal.

6. The flash memory cell of claim 5 wherein said gate element further comprises a layer of polysilicon.

7. The flash memory cell of claim 1 comprising a spacer adjacent to said gate element and said charge storage element, wherein said spacer comprises a material selected from the group consisting of: an oxide, and a nitride.

8. A flash memory array comprising:
a plurality of word lines;
a plurality of bit lines that traverse a substrate orthogonal to said plurality of word lines; and
a plurality of charge storage elements adjacent to said plurality of word lines, wherein said charge storage elements each comprise a first layer comprising silicon-rich silicon nitride and a second layer comprising silicon nitride, wherein said first layer comprises a higher silicon-to-nitrogen ratio than said second layer.

9. The flash memory array of claim 8 wherein said charge storage elements each comprise a third layer comprising silicon nitride, wherein said first layer is sandwiched between said second layer and said third layer, and wherein said first layer comprises a higher silicon-to-nitrogen ratio than said third layer.

10. The flash memory array of claim 8 wherein a tunnel oxide layer is disposed between said charge storage elements and said substrate.

11. The flash memory array of claim 8 wherein a layer of material is disposed between said charge storage elements and said word lines, said material selected from the group consisting of: an oxide layer, and a high dielectric material.

12. The flash memory array of claim 8 further comprising gate elements adjacent to said word lines, said gate elements comprising a layer of material selected from the group consisting of: a metal silicide; a metal nitride, and a metal.

13. The flash memory array of claim 12 wherein said gate elements further comprise a layer of polysilicon.

14. The flash memory array of claim 8 further comprising spacers adjacent to said word lines and said charge storage elements, wherein said spacers comprise a material selected from the group consisting of: an oxide, and a nitride.

15. A method of forming a memory cell in a flash memory array, said method comprising:
forming regions in a substrate, said regions comprising a source and a drain;
depositing a first layer comprising silicon-rich silicon nitride;
depositing a second layer comprising silicon nitride, wherein said first layer comprises a higher silicon-to-nitrogen ratio than said second layer, said first and second layers comprising a charge storage region; and
forming a gate element adjacent said charge storage region.

16. The method of claim 15 further comprising depositing a third layer comprising silicon nitride before said first layer is deposited, wherein said first layer is sandwiched between said second layer and said third layer, and wherein said first layer comprises a higher silicon-to-nitrogen ratio than said third layer.

17. The method of claim 15 further comprising forming a layer of material between said charge storage element and said gate element, said material selected from the group consisting of: an oxide, and a high dielectric constant material.

18. The method of claim 15 further comprising forming a tunnel oxide layer between said charge storage region and said substrate.

19. The method of claim 15 wherein said gate region comprises materials selected from the group consisting of: a metal silicide; a metal nitride, a metal, and polysilicon.

20. The method of claim 15 further comprising forming a spacer adjacent to said gate element and said charge storage region, wherein said spacer comprises a material selected from the group consisting of: an oxide and a nitride.
